(19) United States
(12) Patent Application Publication
(10) Pub. No.: US 2019/0246516 A1
(43) Pub. Date: Aug. 8, 2019

(54) THREE-IN-ONE ASSEMBLED GUIDE RAIL STRUCTURE

(71) Applicant: Kunshan Lemtech Slide Technology Co., Ltd., Kunshan City (CN)

(72) Inventor: CHI FENG HSU, New Taipei City (TW)

(21) Appl. No.: 16/110,591

(22) Filed: Aug. 23, 2018

(30) Foreign Application Priority Data
Feb. 7, 2018 (CN) 201820207903.0

(51) Int. Cl. H05K 7/18; A47B 88/407; A47B 88/43

(52) U.S. Cl. CPC H05K 7/183; A47B 88/43; A47B 88/407

(57) ABSTRACT

A three-in-one assembled guide rail structure is provided, a guide rail body includes a connecting member, a support bracket includes a first connecting surface and a second connecting surface provided with two connecting thread holes. A corresponding location of the connecting thread hole corresponding to the first connecting surface is provided with a corresponding first circular hole. Each group of the corresponding connecting thread hole and the first circular hole are fitted and provided with a stud, a guide spring, and a first thread insert.

### BACKGROUND OF THE INVENTION

### Field of the Invention

The utility model relates to the technical field of guide rail structures, and more particularly, to a three-in-one assembled guide rail structure.

### Description of Related Art

A guide rail is a connection structure between a server and a cabinet. Existing cabinets include cabinets of three standards, namely 9.5 mm square hole, 7.1 mm circular hole, and 10-32 mm threaded hole. In the prior art, it is required to manufacture different guide rails to satisfy mounting holes corresponding to the above three types of cabinets, which leads to a poor universality of the guide rails.

### SUMMARY OF THE INVENTION

For the above problems, the utility model provides a three-in-one assembled guide rail structure, which may be simultaneously applicable to mounting holes corresponding to three types of cabinets, providing a good universality of the guide rail.

A three-in-one assembled guide rail structure includes a guide rail body. The guide rail body includes a connecting member for fixing a mounting hole of a cabinet. An end surface of the connecting member corresponding to the mounting hole is provided with a support bracket, which includes a first connecting surface and a second connecting surface. The first connecting surface and the second connecting surface combine to form an integral structure by two parallel connecting plates. The first connecting surface and the second connecting surface are arranged in parallel. A mounting cavity is formed between the first connecting surface and the second connecting surface. The first connecting surface and the second connecting surface are in parallel to an end surface arrangement provided with the mounting hole of the cabinet. The first connecting surface fits to the end surface arrangement provided with the mounting hole of the cabinet. The second connecting surface is provided with two connecting thread holes. A corresponding location of the connecting thread hole corresponding to the first connecting surface is provided with a corresponding first circular hole. Each group of the corresponding connecting thread hole and the first circular hole are fitted and provided with a stud, a guide spring, and a first thread insert. An inner end of the stud is provided with a threaded section. A terminal segment of the threaded section is provided with a first stop structure, and a remaining segment of the stud is a smooth surface structure. An outer end surface of the stud is provided with an inner groove for screwing or unscrewing a corresponding model of screwdriver. The first thread insert includes a central through hole, an inner end second stop structure, a middle segment circular guide ring, and an outer end circular guide ring. A diameter of the middle segment circular guide ring is greater than that of the outer end circular guide ring. A region of the inner end second stop structure is larger than that of the middle segment circular guide ring. A region of the first circular hole is smaller than that of the inner end second stop structure. A diameter of the first circular hole is not less than that of the middle segment circular guide ring. The guide spring is sleeved at a location of the stud between the mounting cavities. The first thread insert is sleeved on the stud, and the second stop structure of the first thread insert is positioned in the mounting cavity. Two ends of the guide spring are respectively top mounted on the first stop structure and the second stop structure. The threaded section of the stud is in threaded connection to the corresponding connecting thread hole.

Further,

the diameter of the middle segment circular guide ring is consistent with a side length of a square hole of the cabinet to be mounted, and at this moment the middle segment circular guide ring penetrates through the corresponding square hole to complete installation of the guide rail.

The diameter of the outer end circular guide ring is consistent with a hole diameter of a circular hole of the cabinet to be mounted, and at this moment the outer end circular guide ring penetrates through the corresponding circular hole to complete installation of the guide rail.

A diameter of a smooth surface portion of the stud is consistent with a hole diameter of a threaded hole of the cabinet to be mounted, and at this moment an outer end smooth surface of the stud penetrates through the corresponding threaded hole to complete installation of the guide rail.

An inner groove portion of the stud outwardly protrudes an outer end surface of the threaded hole to ensure a screwdriver to screw or unscrew the stud.

The inner groove includes but is not limited to a straight groove or a cross groove.

The first connecting surface is provided with a second threaded hole at a central location of length connection between two first circular holes. The second threaded hole is in threaded connection to an outwardly protruding guide thread insert. The diameter of an outwardly protruding portion of the guide thread insert is not greater than the hole diameter of the circular hole of the cabinet to be mounted. The guide thread insert is removed when the cabinet to be mounted has a threaded hole.

A space between the guide thread insert and a center shaft of the first thread insert adjacent to the guide thread insert is a spacing distance between the square hole, the circular hole or the threaded hole of the cabinet to be mounted, which may ensure the universality of the entire structure.

According to the utility model, a cabinet mounting structure for a guide rail is manufactured, which is simultaneously applicable to cabinets of three standards, including 9.5 mm square hole, 7.1 mm circular hole and 10-32 mm threaded hole, thereby providing a good universality of the guide rail.

### BRIEF DESCRIPTION OF THE DRAWINGS

FIG. 1 is a structural schematic diagram of an exploded view according to the utility model;

FIG. 2 is a structural schematic diagram of a perspective view according to the utility model;

FIG. 3 is a perspective view suitable for a square hole according to the utility model;

FIG. 4 is a perspective view suitable for a circular hole according to the utility model; and

FIG. 5 is a perspective view suitable for a threaded hole according to the utility model.

### DETAILED DESCRIPTION OF THE PREFERRED EMBODIMENT

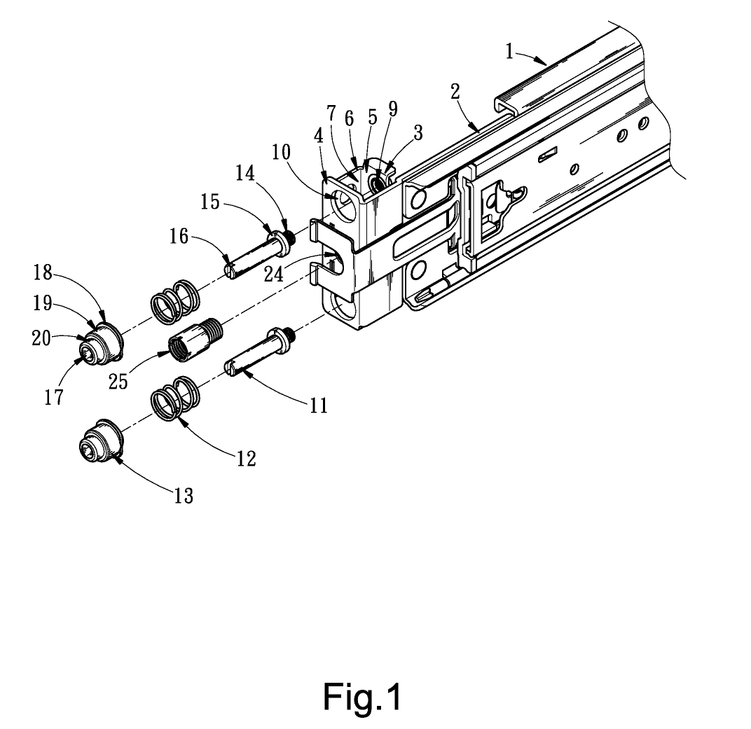

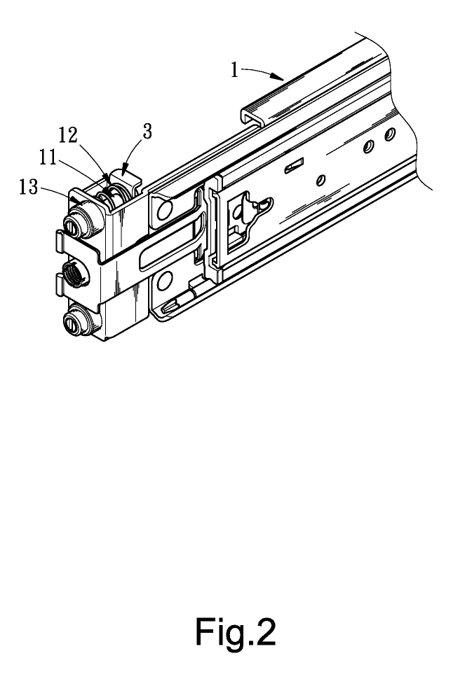

A three-in-one assembled guide rail structure as shown in FIG. 1-FIG. 5 includes a guide rail body 1. The guide rail body 1 includes a connecting member 2 for fixing a mounting hole of a cabinet. An end surface of the connecting member 2 corresponding to the mounting hole is provided with a support bracket 3, which includes a first connecting surface 4 and a second connecting surface 5. The first connecting surface 4 and the second connecting surface 5 combine to form an integral structure by two parallel connecting plates 6. The first connecting surface 4 and the second connecting surface 5 are arranged in parallel. A mounting cavity 7 is formed between the first connecting surface 4 and the second connecting surface 5. The first connecting surface 4 and the second connecting surface 5 are in parallel to an end surface arrangement provided with the mounting hole of the cabinet 8. The first connecting surface 4 fits to the end surface arrangement provided with the mounting hole of the cabinet 8. The second connecting surface 5 is provided with two connecting thread holes 9. A corresponding location of the connecting thread hole 9 corresponding to the first connecting surface 4 is provided with a corresponding first circular hole 10. Each group of the corresponding connecting thread hole 9 and the first circular hole 10 are fitted and provided with a stud 11, a guide spring 12, and a first thread insert 13. An inner end of the stud 11 is provided with a threaded section 14. A terminal segment of the threaded section 14 is provided with a first stop structure 15, and a remaining segment of the stud 11 is a smooth surface structure. An outer end surface of the stud 11 is provided with an inner groove 16 for screwing or unscrewing a corresponding model of screwdriver. The first thread insert 13 includes a central through hole 17, an inner end second stop structure 18, a middle segment circular guide ring 19, and an outer end circular guide ring 20. A diameter of the middle segment circular guide ring 19 is greater than that of the outer end circular guide ring 20. A region of the inner end second stop structure 18 is larger than that of the middle segment circular guide ring 19. A region of the first circular hole 10 is smaller than that of the inner end second stop structure 18. A diameter of the first circular hole 10 is not less than that of the middle segment circular guide ring 19. The guide spring 12 is sleeved at a location of the stud 11 between the mounting cavities 7. The first thread insert 13 is sleeved on the stud 11, and the second stop structure 18 of the first thread insert 13 is positioned in the mounting cavity 7. Two ends of the guide spring 12 are respectively top mounted on the first stop structure 15 and the second stop structure 18. The threaded section 14 of the stud 11 is in threaded connection to the corresponding connecting thread hole 9.

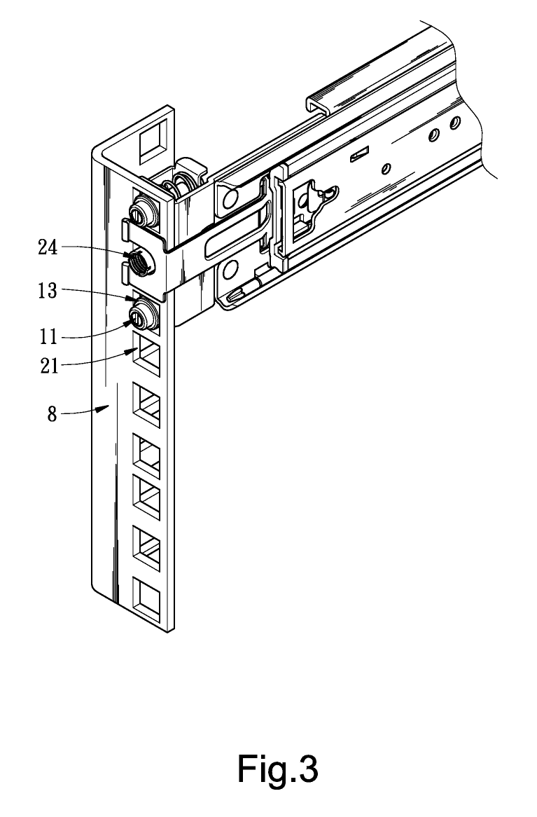

The diameter of the middle segment circular guide ring 19 is consistent with a side length of a square hole 21 of the cabinet 8 to be mounted, and at this moment the middle segment circular guide ring 19 penetrates through the corresponding square hole 21 to complete installation of the guide rail (referring to FIG. 3). The side length of the square hole in a specific embodiment is 9.5 mm.

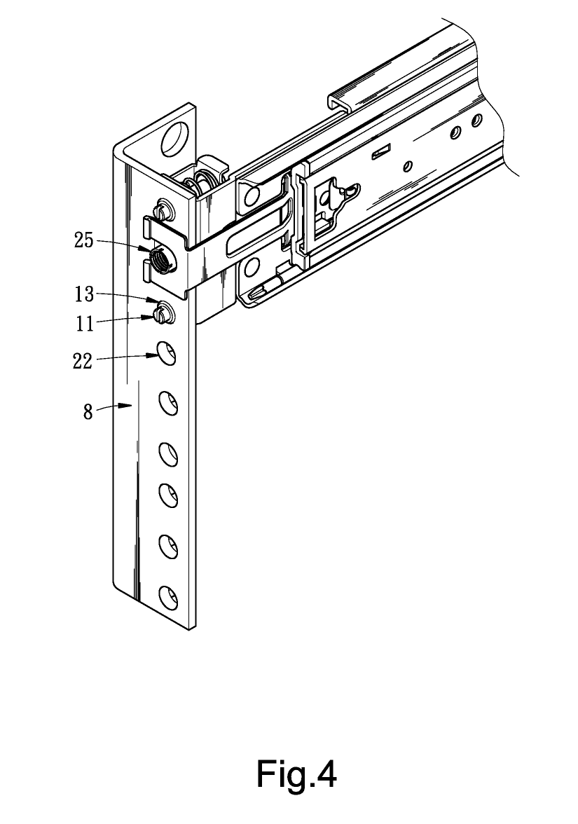

The diameter of the outer end circular guide ring 20 is consistent with a hole diameter of a circular hole 22 of the cabinet 8 to be mounted, and at this moment the middle segment circular guide ring 19 of the first thread insert 13 is sprung back into the mounting cavity 7. The outer end circular guide ring 20 penetrates through the corresponding circular hole 22 to complete installation of the guide rail (referring to FIG. 4). The hole diameter of the circular hole in a specific embodiment is 7.1 mm.

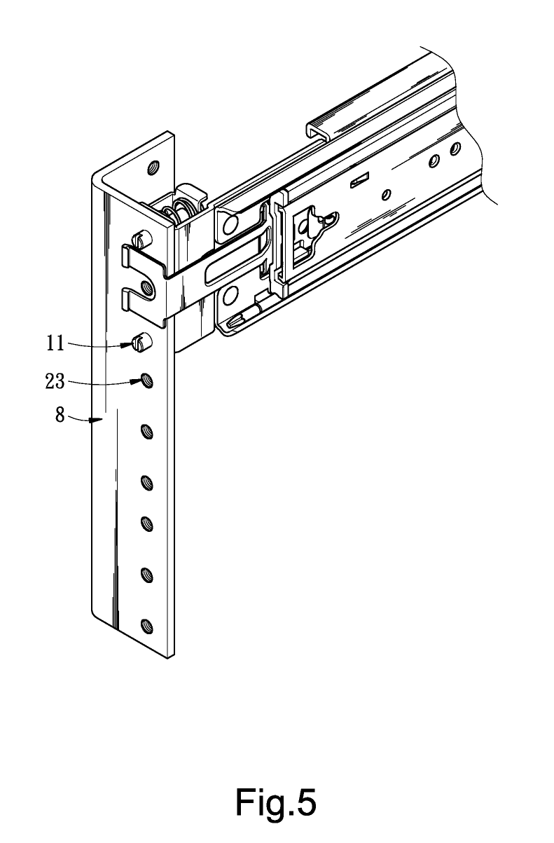

A diameter of a smooth surface portion of the stud 11 is consistent with a hole diameter of a threaded hole 23 of the cabinet 8 to be mounted, and at this moment the whole first thread insert 13 is sprung back into the mounting cavity 7 under the action of the guide spring 12. An outer end smooth surface of the stud 11 penetrates through the corresponding threaded hole 23 to complete installation of the guide rail. A portion corresponding to the inner groove 16 of the stud 11 outwardly protrudes an outer end surface of the threaded hole 23 to ensure a screwdriver to screw or unscrew the stud 11 (referring to FIG. 5).The threaded hole in a specific embodiment is a 10-32 UNF threaded hole.

The inner groove 16 includes but is not limited to a straight groove or a cross groove.

The first connecting surface 4 is provided with a second threaded hole 24 at a central location of length connection between two first circular holes 10. The second threaded hole 24 is in threaded connection to an outwardly protruding guide thread insert 25. The diameter of an outwardly protruding portion of the guide thread insert 25 is not greater than the hole diameter of the circular hole 22 of the cabinet 8 to be mounted. The guide thread insert 25 (referring to FIG. 5) is removed when the cabinet 8 to be mounted has a threaded hole 23.

A space between the guide thread insert 25 and a center shaft of the first thread insert 13 adjacent to the guide thread insert is a spacing distance between the square hole 21, the circular hole 22 or the threaded hole 23 of the cabinet 8 to be mounted, which may ensure the universality of the entire structure.

The specific embodiments of the utility model are described in detail above. However, contents thereof are merely preferred embodiments created by the utility model, and are not deemed to be intended for limiting the scope of implementation created by the utility model. Any equivalent variations and improvements or the like made in accordance with the scope of implementation created by the utility model shall be deemed to be within the scope of this patent.

What is claimed is:

1. A three-in-one assembled guide rail structure, comprising a guide rail body, the guide rail body comprising a connecting member for fixing a mounting hole of a cabinet, an end surface of the connecting member corresponding to the mounting hole being provided with a support bracket, the support bracket comprising a first connecting surface and a second connecting surface, the first connecting surface and the second connecting surface combining to form an integral structure by two parallel connecting plates, the first connecting surface and the second connecting surface being arranged in parallel, a mounting cavity being formed between the first connecting surface and the second connecting surface, the first connecting surface and the second connecting surface being in parallel to an end surface arrangement provided with the mounting hole of the cabinet, the first connecting surface fitting to the end surface arrangement provided with the mounting hole of the cabinet, the second connecting surface being provided with two connecting thread holes, a corresponding location of the connecting thread hole corresponding to the first connecting surface being provided with a corresponding first circular hole, each group of the corresponding connecting thread hole and the first circular hole being fitted and provided with a stud, a guide spring and a first thread insert, an inner end of the stud being provided with a threaded section, a terminal segment of the threaded section being provided with a first stop structure, a remaining segment of the stud being a smooth surface structure, an outer end surface of the stud being provided with an inner groove for screwing or unscrewing a corresponding model of screwdriver, the first thread insert comprising a central through hole, an inner end second stop structure, a middle segment circular guide ring and an outer end circular guide ring, a diameter of the middle segment circular guide ring being greater than that of the outer end circular guide ring, a region of the inner end second stop structure being larger than that of the middle segment circular guide ring, a region of the first circular hole being smaller than that of the inner end second stop structure, a diameter of the first circular hole being not less than that of the middle segment circular guide ring, the guide spring being sleeved at a location of the stud between the mounting cavities, the first thread insert being sleeved on the stud, the second stop structure of the first thread insert being positioned in the mounting cavity, and two ends of the guide spring being respectively top mounted on the first stop structure and the second stop structure, and the threaded section of the stud being in threaded connection to the corresponding connecting thread hole.

2. The three-in-one assembled guide rail structure according to claim 1, wherein the diameter of the middle segment circular guide ring is consistent with a side length of a square hole of the cabinet to be mounted, and at this moment the middle segment circular guide ring penetrates through the corresponding square hole to complete installation of the guide rail.

3. The three-in-one assembled guide rail structure according to claim 1, wherein the diameter of the outer end circular guide ring is consistent with a hole diameter of a circular hole of the cabinet to be mounted, and at this moment the outer end circular guide ring penetrates through the corresponding circular hole to complete installation of the guide rail.

4. The three-in-one assembled guide rail structure according to claim 1, wherein a diameter of a smooth surface portion of the stud is consistent with a hole diameter of a threaded hole of the cabinet to be mounted, and at this moment an outer end smooth surface of the stud penetrates through the corresponding threaded hole to complete installation of the guide rail.

5. The three-in-one assembled guide rail structure according to claim 1, wherein an inner groove portion of the stud outwardly protrudes an outer end surface of the threaded hole.

6. The three-in-one assembled guide rail structure according to claim 1, wherein the inner groove comprises but is not limited to a straight groove or a cross groove.

7. The three-in-one assembled guide rail structure according to claim 1, wherein the first connecting surface is provided with a second threaded hole at a central location of length connection between two first circular holes, and the second threaded hole is in threaded connection to an outwardly protruding guide thread insert.

8. The three-in-one assembled guide rail structure according to claim 7, wherein a space between the guide thread insert and a center shaft of the first thread insert adjacent to the guide thread insert is a spacing distance between the square hole, the circular hole or the threaded hole of the cabinet to be mounted.
